(19) United States
(12) Patent Application Publication
(10) Pub. No.: US 2026/0020178 A1
(43) Pub. Date: Jan. 15, 2026

(54) Server System Chassis Rear Wall System

(71) Applicant: Dell Products L.P., Round Rock, TX (US)

(72) Inventors: Haocheng Ku, Taipei City (TW); Yufeng Lin, Taipei City (TW); Yi-Chang Chen, New Taipei City (TW); Eduardo Escamilla, Round Rock, TX (US)

(21) Appl. No.: 18/768,217

(22) Filed: Jul. 10, 2024

(51) Int. Cl. H05K 7/14

(52) U.S. Cl. CPC H05K 7/1487

(57) ABSTRACT

A rear wall system for an information handling system chassis. The rear wall system includes a rear wall component, the rear wall component comprising: a center rear wall component portion; a right rear wall component portion; and, a left rear wall component portion, the center rear wall component portion, the right rear wall component portion and the left rear wall component portion being constructed from a single piece of material, the center rear wall component portion horizontally extending between the right rear wall component portion and the left rear wall component portion, the right rear wall component portion extending substantially perpendicularly inward from the center rear wall component portion, the left rear wall component portion extending substantially perpendicularly inward from the center rear wall component portion.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a server type information handling system with a rear wall system.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3A and 3B, generally referred to as FIG. 3, respectively show generalized front and rear perspective views of an example server type information handling system.

FIGS. 4A, 4B and 4C, generally referred to as FIG. 4, respectively show a top view of a rear portion of a server system a rear view of a portion of a server system and a perspective view of a portion of a server system.

FIG. 5 shows a top view of a right portion of a rear wall system of a server system.

FIG. 6 shows a top view of a left portion of a rear wall system of a server system.

FIGS. 7A, 7B, 7C, 7D, 7E, 7F and 7G, respectively show perspective view, a top view, a bottom view, a front view, a rear view, a right view and a left view of a rear wall component.

### DETAILED DESCRIPTION

Various aspects of the disclosure include an appreciation that it is known to provide a server type information handling system which can support a plurality of card configurations. Various aspects of the disclosure include an appreciation that the plurality of card configurations can include configurations which includes peripheral component interconnect express (PCIe) card configurations, including full height PCIe card configurations, open compute project (OCP) card configurations, boot optimized storage solution (BOSS) card configurations, data center secure control module (DC-SCM) card configurations, or a combination thereof..

Various aspects of the disclosure include an appreciation the with known server type information handling systems it can be challenging to provide a single server chassis design which can support a plurality of card configurations. Various aspects of the disclosure include an appreciation the with known server type information handling systems it can be challenging to provide a rear wall chassis structure which has sufficient flexibility to support a plurality of card configurations. Various aspects of the disclosure include an appreciation with it would be desirable to provide a single server chassis design which can support a plurality of card configurations. Various aspects of the disclosure include an appreciation with it would be desirable to provide a rear wall structure to which a rear component handle can be attached.

A system and method are disclosed for providing a rear wall system which can support a plurality of card configurations. In certain embodiments, the rear wall system includes one or more integrated riser attachment features. In certain embodiments, the rear wall system includes an integrated rear component handle.

In certain embodiments, the rear wall system is configured to span across a large percentage (i.e., substantially 75%) of a rear wall of a server chassis. In certain embodiments, the rear wall system spans between portions of one or more power supply unit bays. In certain embodiments, the rear wall system is die cast. In certain embodiments, the rear wall system enhances the strength of the rear wall. In certain embodiments, the rear wall system enhances the strength of the rear wall in a horizontal direction.

In certain embodiments, the rear wall system includes a plurality of upper riser features. In certain embodiments, the rear wall system includes three upper riser features. In certain embodiments, the upper riser features are interconnected. In certain embodiments, the upper riser features secure respective risers to the server chassis. In certain embodiments, one of the upper riser features is used to attach an upper middle riser to the server chassis. In certain embodiments, the rear wall system includes at least one lower riser feature. In certain embodiments, the rear wall lower riser feature is configured to allow a lower riser to be guided into the server chassis.

In certain embodiments, the rear wall system includes a ground connection portion. In certain embodiments, the ground connection portion is configured to physically connect a grounding kit to the server chassis. In certain embodiments, the ground connection portion is configured to physically connect a grounding kit which conforms to a network equipment building system (NEBS) standard to the server chassis. In certain embodiments, the rear wall component includes the ground connection portion.

In certain embodiments, the rear wall component is configured to provide a gripping area. In certain embodiments, the gripping areas provide the rear wall system an integrated rear component handle.

Accordingly, the rear wall system advantageously provides an integrated system which enhances rear wall strength, facilitates riser installation and functions as a rear component handle. In certain embodiments, the rear wall system includes a rear wall component which is constructed from a single piece of material which enhances rear wall strength, facilitates riser installation and functions as a rear component handle.

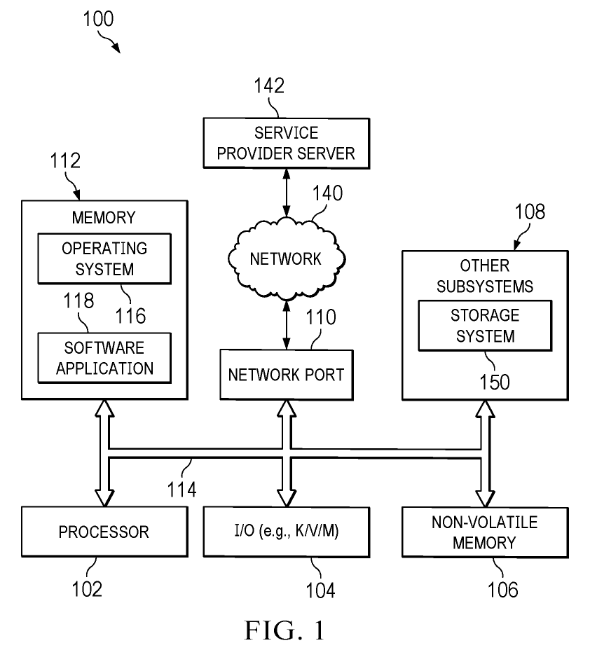

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include an OCP FLOP retention system 150 and an OCP card mounting system 152. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the information handling system 100 includes an information handling system chassis which includes a rear wall system 150 which includes one or more integrated riser attachment features. In certain embodiments, the rear wall system includes an integrated rear component handle.

In certain embodiments, the rear wall system 150 is configured to span across a large percentage (i.e., substantially 75%) of a rear wall of a server chassis. In certain embodiments, the rear wall system 150 spans between portions of one or more power supply unit bays. In certain embodiments, the rear wall system is die cast. In certain embodiments, the rear wall system 150 enhances the strength of the rear wall. In certain embodiments, the rear wall system 150 enhances the strength of the rear wall in a horizontal direction.

In certain embodiments, the rear wall system 150 includes a plurality of upper riser features. In certain embodiments, the rear wall system includes three upper riser features. In certain embodiments, the upper riser features are interconnected. In certain embodiments, the upper riser features secure respective risers to the server chassis. In certain embodiments, one of the upper riser features is used to attach an upper middle riser to the server chassis. In certain embodiments, the rear wall system includes at least one lower riser feature. In certain embodiments, the rear wall lower riser feature is configured to allow a lower riser to be guided into the server chassis.

In certain embodiments, the rear wall system 150 includes a ground connection portion. In certain embodiments, the ground connection portion is configured to physically connect a grounding kit to the server chassis. In certain embodiments, the ground connection portion is configured to physically connect a grounding kit which conforms to a network equipment building system (NEBS) standard to the server chassis. In certain embodiments, the rear wall component includes the ground connection portion.

In certain embodiments, the rear wall component is configured to provide a gripping area. In certain embodiments, the gripping areas provide the rear wall system an integrated rear component handle.

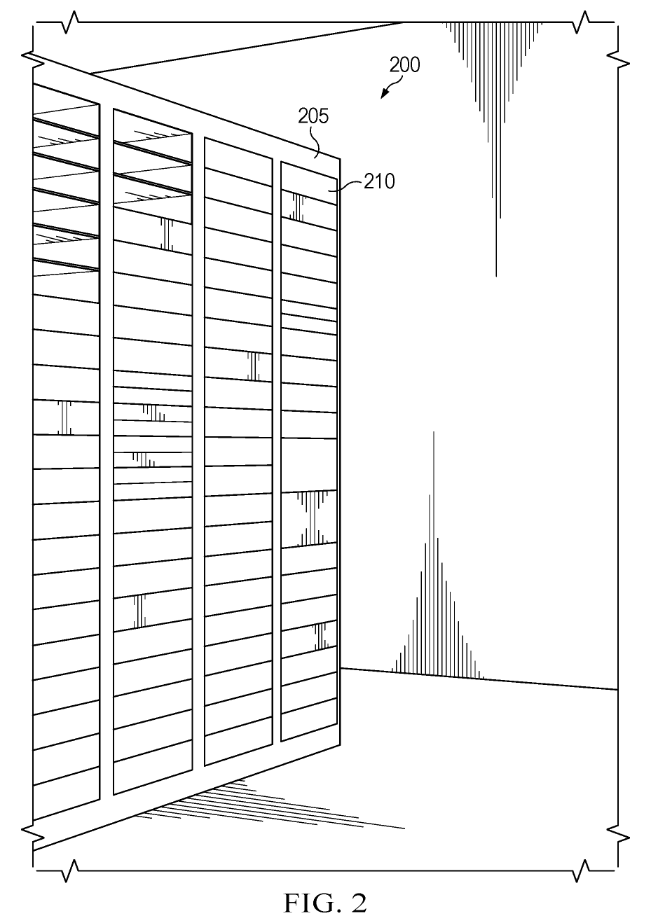

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100 as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit and a 4U rack unit. In general, a 1U rack unit is substantially (i.e., +/-20%) 1.75” high, a 2U rack unit is substantially (i.e., +/-20%) 3.5” high and a 4U rack height is substantially (i.e., +/-20%) 7.0” high.

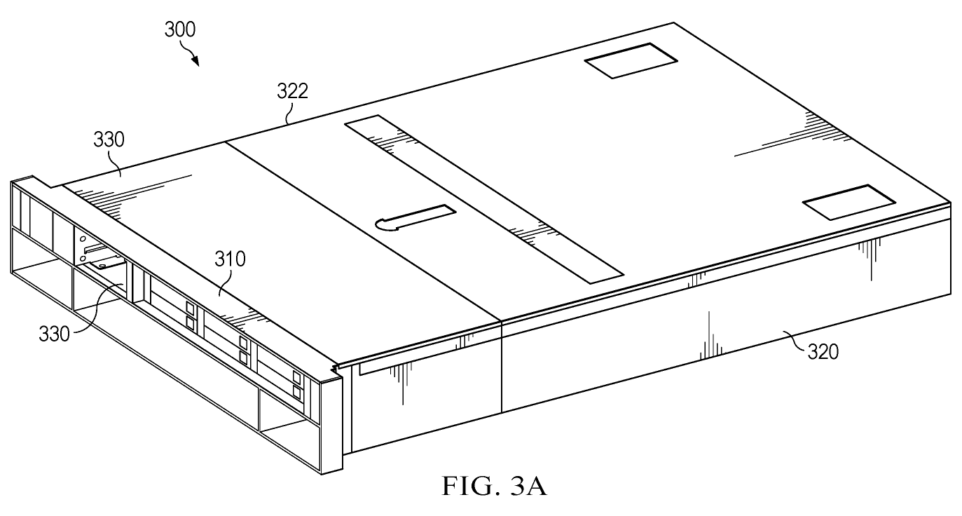

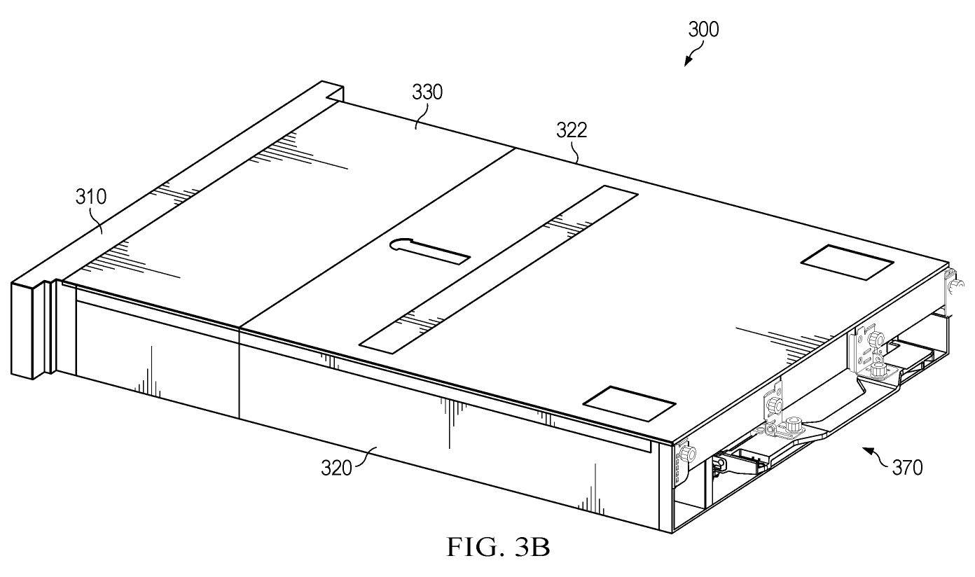

FIG. 3A and 3B, generally referred to as FIG. 3, respectively show generalized front and rear perspective views of an example server type information handling system. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the blade type information handing system 300 includes a bay 350 via which components may be mounted to the blade type information handling system.

In certain embodiments, the server type information handling system includes a rear wall system 370. In certain embodiments, the rear wall system 370 corresponds to rear wall system 150. In certain embodiments, the server type information handling system 300 includes an information handling system chassis which includes a rear wall system 370 which includes one or more integrated riser attachment features. In certain embodiments, the rear wall system includes an integrated rear component handle.

In certain embodiments, the rear wall system 370 is configured to span across a large percentage (i.e., substantially 75%) of a rear wall of a server chassis. In certain embodiments, the rear wall system 370 spans between portions of one or more power supply unit bays. In certain embodiments, the rear wall system is die cast. In certain embodiments, the rear wall system 370 enhances the strength of the rear wall. In certain embodiments, the rear wall system 370 enhances the strength of the rear wall in a horizontal direction.

In certain embodiments, the rear wall system 370 includes a plurality of upper riser features. In certain embodiments, the rear wall system includes three upper riser features. In certain embodiments, the upper riser features are interconnected. In certain embodiments, the upper riser features secure respective risers to the server chassis. In certain embodiments, one of the upper riser features is used to attach an upper middle riser to the server chassis. In certain embodiments, the rear wall system includes at least one lower riser feature. In certain embodiments, the rear wall lower riser feature is configured to allow a lower riser to be guided into the server chassis.

In certain embodiments, the rear wall system 370 includes a ground connection portion. In certain embodiments, the ground connection portion is configured to physically connect a grounding kit to the server chassis. In certain embodiments, the ground connection portion is configured to physically connect a grounding kit which conforms to a network equipment building system (NEBS) standard to the server chassis. In certain embodiments, the rear wall component includes the ground connection portion.

In certain embodiments, the rear wall component is configured to provide a gripping area. In certain embodiments, the gripping areas provide the rear wall system an integrated rear component handle.

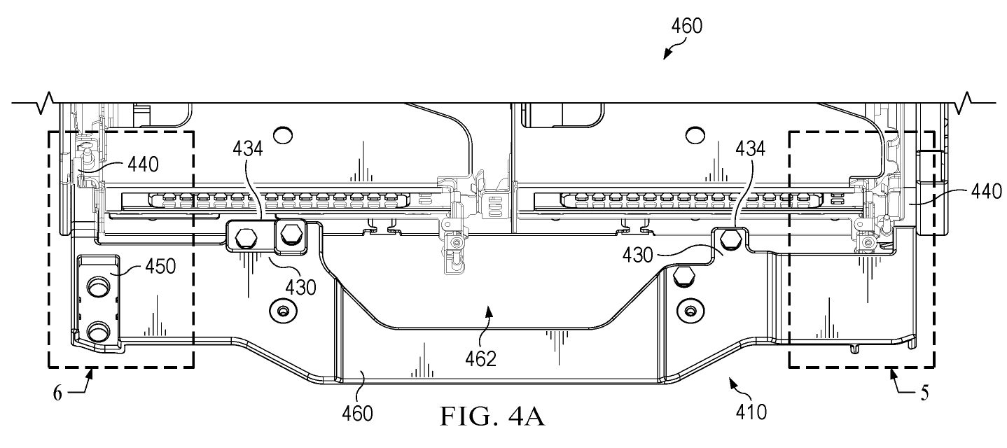

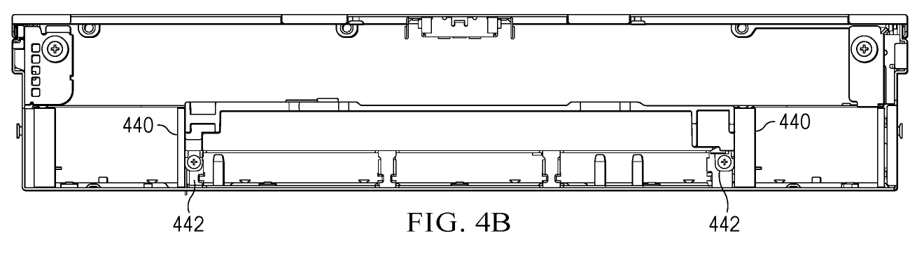

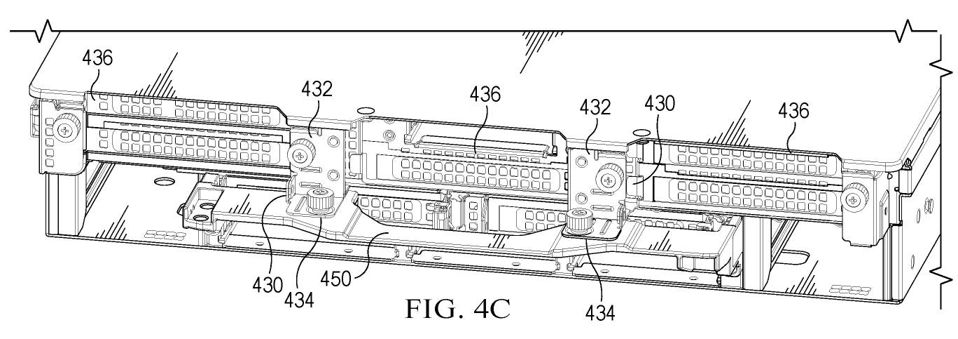

FIGS. 4A, 4B and 4C, generally referred to as FIG. 4, respectively show a plurality of views of a rear portion of a server type information handling system 400. More specifically, FIG. 4A shows a top view of a rear portion of a server type information handling system 400. FIG. 4B shows a rear view of a portion of a server system. FIG. 4C shows a perspective view of a portion of a server type information handling system 400.

In certain embodiments, the server type information handling system 400 includes a rear wall system 410. In certain embodiments, the rear wall system 410 corresponds to rear wall system 150. In certain embodiments, the server type information handling system 400 includes an information handling system chassis which includes a rear wall system 410. In certain embodiments, the rear wall system 410 includes one or more integrated riser attachment features. In certain embodiments, the rear wall system includes an integrated rear component handle. In certain embodiments, the rear wall system 410 includes a rear wall component 420.

In certain embodiments, the rear wall component 420 is configured to horizontally span across a large percentage (i.e., substantially 75%) of a rear wall of a server chassis. In certain embodiments, the rear wall component 420 horizontally spans between of one or more inside walls of respective power supply unit bays 422. In certain embodiments, the rear wall component 420 is die cast. In certain embodiments, the rear wall system 410 enhances the strength of the rear wall. In certain embodiments, the rear wall system 410 enhances the strength of the rear wall in a horizontal direction.

In certain embodiments, the rear wall system 410 includes a plurality of upper riser features 430. In certain embodiments, the rear wall system 410 includes at least two upper riser features. In certain embodiments, each upper riser feature 430 includes a rear wall riser bracket 432, a rear wall component riser portion 434, or a combination thereof. In certain embodiments, the upper riser features enable a plurality of risers 436 to be interconnected. In certain embodiments, the upper riser features secure a plurality of risers 436 to the server chassis. In certain embodiments, the upper riser features are used to attach an upper middle riser 436 to the server chassis.

In certain embodiments, the rear wall riser bracket 432 is substantially L shaped. In certain embodiments, a lower portion of the rear wall riser bracket 432 is physically coupled to a respective rear wall component riser portion 434. In certain embodiments, an upper portion of the rear wall riser bracket 432 is physically coupled to a riser 436. In certain embodiments, the upper portion of the rear wall riser bracket 432 is coupled to a plurality of risers 436. In certain embodiments, the upper portion of the rear wall riser bracket 432 is coupled to an inside portion of one riser 436 and an outside portion of a middle riser 436.

In certain embodiments, the rear wall system 410 includes at least one lower riser feature 440. In certain embodiments, the lower riser feature 440 includes at least one lower riser attachment portion 442, at least one lower riser guide portion 442, or a combination thereof. In certain embodiments, a lower riser attachment portion 442 is used to physically attach a lower riser 446 to the server chassis. In certain embodiments, the rear wall lower riser guide portion 444 is configured to allow a lower riser to be guided into the server chassis, to be positioned within the server chassis, or a combination thereof. In certain embodiments, the rear wall component 420 includes the lower rear wall component riser feature 440. In certain embodiments, the rear wall component 420 includes the lower riser attachment portion 442, the lower riser guide portion 444, or a combination thereof.

In certain embodiments, the rear wall system 410 includes a ground connection portion 450. In certain embodiments, the ground connection portion 450 is configured to physically connect a grounding kit to the server chassis. In certain embodiments, the ground connection portion 450 is configured to physically connect a grounding kit which conforms to a network equipment building system (NEBS) standard to the server chassis. In certain embodiments, the rear wall component 420 includes the ground connection portion 450.

In certain embodiments, the rear wall component 420 is configured to provide a gripping area 460. In certain embodiments, the gripping area 460 provides the rear wall system 410 with an integrated rear component handle. In certain embodiments, the gripping area defines a recess 462 via which fingers of a user may fit between an edge of the rear wall component 420 and a rear wall of the server chassis.

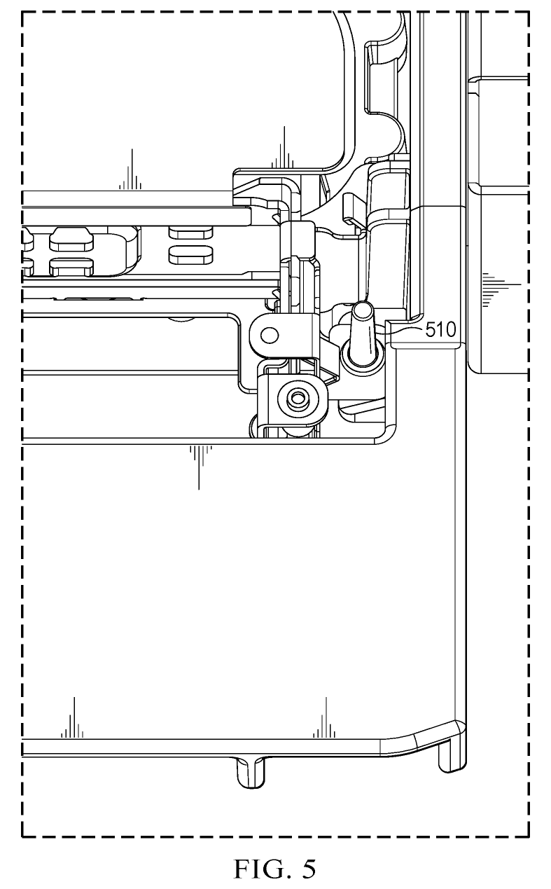

FIG. 5 shows a top view of a right portion 500 of a rear wall system of a server system. In certain embodiments, the rear wall system corresponds to rear wall system 150.

In certain embodiments, the rear wall system includes a right lower riser guide feature 510. In certain embodiments, the right lower riser guide feature 510 is configured to allow a right lower riser to be guided into the server chassis. In certain embodiments, the right lower riser guide feature 510 is configured to allow a right lower riser to be positioned in the server chassis. In certain embodiments, a rear wall component includes the right lower riser guide feature 510.

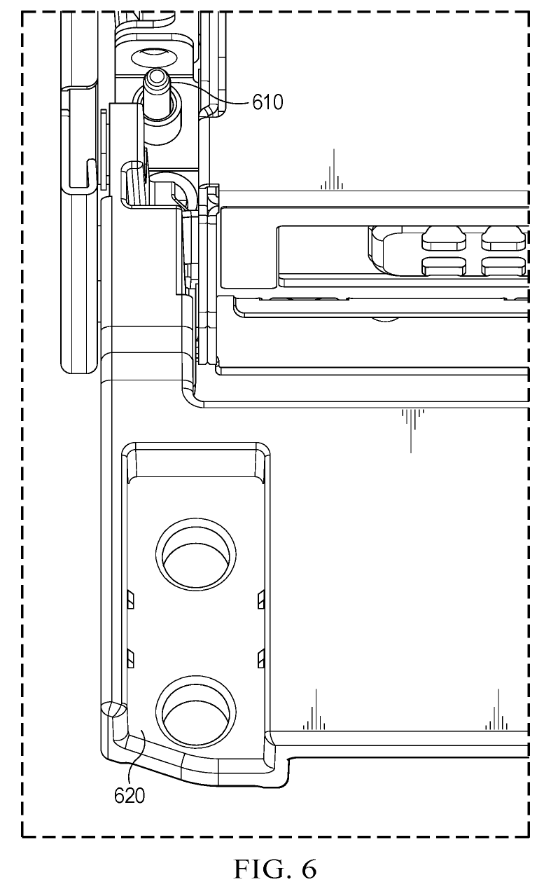

FIG. 6 shows a top view of a left portion 600 of a rear wall system of a server system. In certain embodiments, the rear wall system corresponds to rear wall system 150.

In certain embodiments, the rear wall system includes a left lower riser guide feature 610. In certain embodiments, the left lower riser guide feature 610 is configured to allow a left lower riser to be guided into the server chassis. In certain embodiments, the left lower riser guide feature 610 is configured to allow a left lower riser to be positioned in the server chassis. In certain embodiments, a rear wall component includes the left lower riser guide feature 610.

In certain embodiments, the rear wall system includes a ground connection portion 620. In certain embodiments, the ground connection portion 620 is configured to physically connect a grounding kit to the server chassis. In certain embodiments, the ground connection portion 620 is configured to physically connect a grounding kit which conforms to a network equipment building system (NEBS) standard to the server chassis. In certain embodiments, a rear wall component includes the ground connection portion 620.

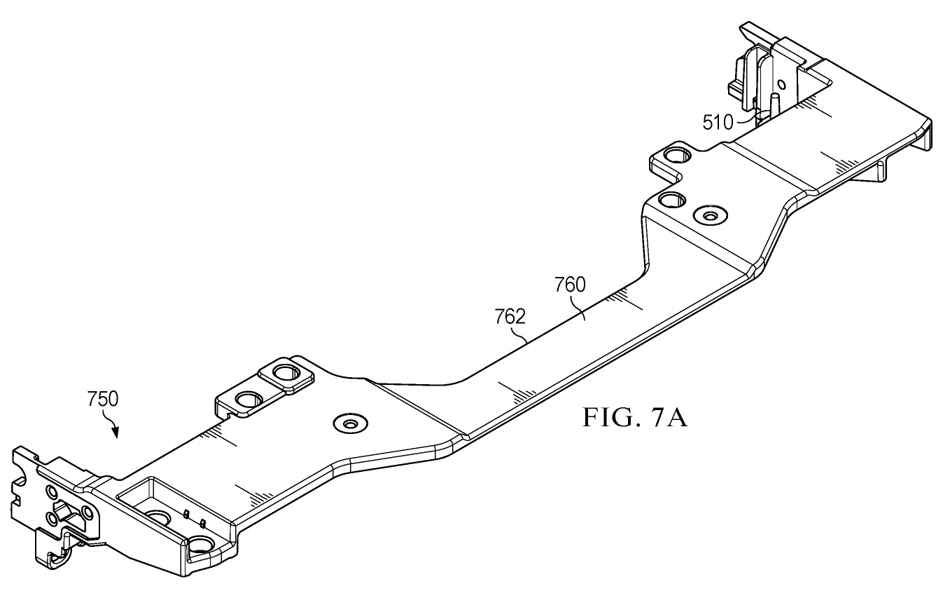

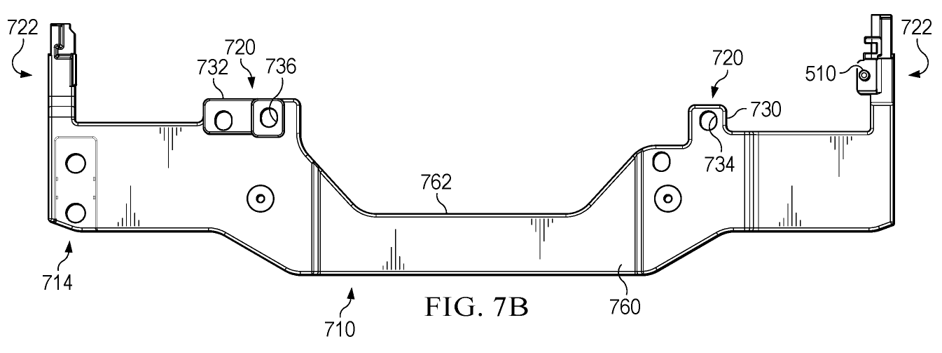

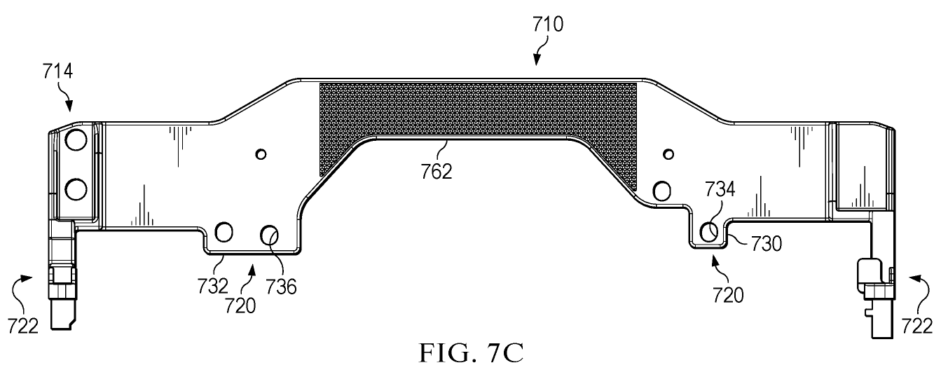

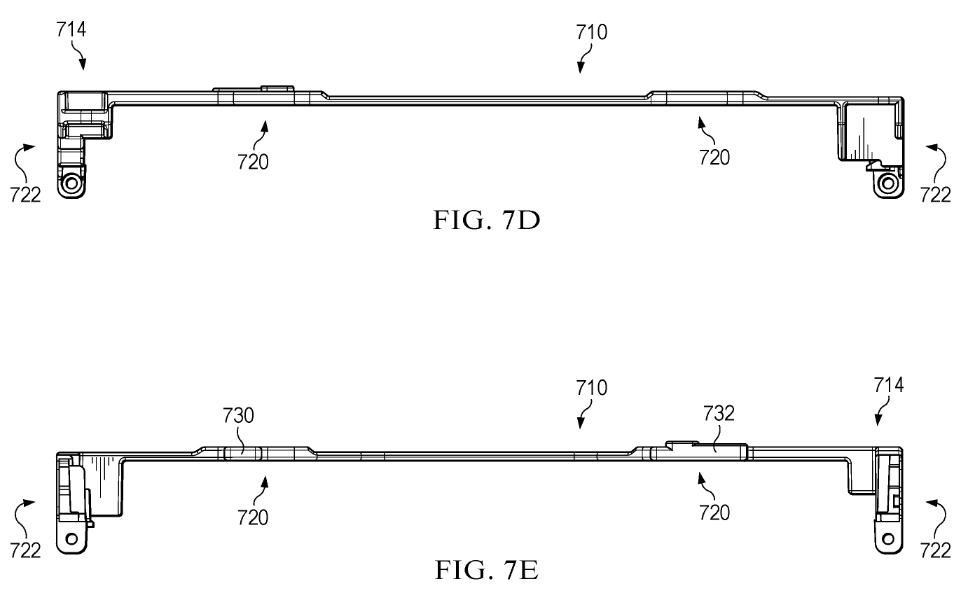

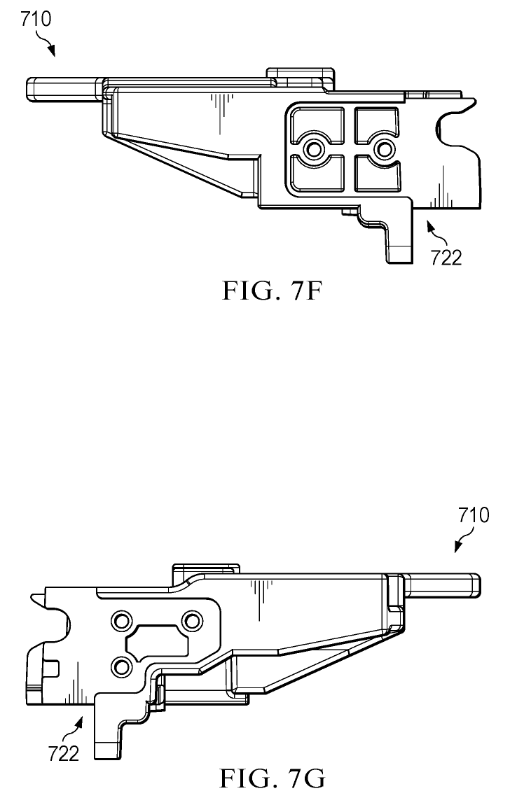

FIGS. 7A, 7B, 7C, 7D, 7E, 7F and 7G, respectively show perspective view, a top view, a bottom view, a front view, a rear view, a right view and a left view of a rear wall component 700. In certain embodiments, the rear wall component 700 corresponds to rear wall component 420.

In certain embodiments, the rear wall component 700 is configured to horizontally span across a large percentage (i.e., substantially 75%) of a rear wall of a server chassis. In certain embodiments, the rear wall component 700 horizontally spans between of one or more inside walls of respective power supply unit bays. In certain embodiments, the rear wall component 700 is die cast. In certain embodiments, the rear wall component 700 enhances the strength of the rear wall. In certain embodiments, the rear wall component 700 enhances the strength of the rear wall in a horizontal direction.

In certain embodiments, the rear wall component 700 includes a center rear wall component portion 710, a right rear wall component portion 712, a left rear wall component portion 714, or a combination thereof. In certain embodiments, the center rear wall component portion 710, the right rear wall component portion 712 and the left rear wall component portion 714 are constructed from a single piece of material. In certain embodiments, the center rear wall component portion 710 horizontally extends between the right rear wall component portion 712 and the left rear wall component portion 714. In certain embodiments, the right rear wall component portion 712 extends substantially perpendicularly inward from the center rear wall component portion 710. In certain embodiments, the left rear wall component portion 712 extends substantially perpendicularly inward from the center rear wall component portion 710. In certain embodiments, the right rear wall component portion 712 is configured to mount the rear wall component 700 to a right portion of a rear wall of a server chassis. In certain embodiments, the left rear wall component portion 714 is configured to mount the rear wall component 700 to a left portion of a rear wall of a server chassis.

In certain embodiments, the rear wall component 700 includes at least one upper rear wall component riser portion 720, at least one lower rear wall riser portion 722, or a combination thereof. In certain embodiments, the center rear wall component portion 710 includes the at least one upper rear wall component riser portion 720. In certain embodiments, the at least one upper rear wall component riser portion 720 includes a right upper rear wall component riser portion 730, a left upper rear wall component riser portion 732, or a combination thereof. In certain embodiments, the right upper wall component riser portion 730 defines a right upper wall riser mounting aperture 734. In certain embodiments, the left upper wall component riser portion 732 defines a left upper wall riser mounting aperture 736.

In certain embodiments, the at least one lower rear wall component riser portion 722 includes a right lower rear wall component riser portion 740, a left lower rear wall component riser portion 742, or a combination thereof. In certain embodiments, the right rear wall component portion 712 includes the right lower rear wall component riser portion 740. In certain embodiments, the right lower wall component riser portion 740 defines a right lower wall riser mounting aperture 744. In certain embodiments, the left lower wall component riser portion 742 defines a left lower wall riser mounting aperture 744.

In certain embodiments, the right lower rear wall component riser portion 730 includes a right lower riser guide feature 746. In certain embodiments, the right lower riser guide feature 746 is configured to allow a right lower riser to be guided into the server chassis. In certain embodiments, the right lower riser guide feature 746 is configured to allow a right lower riser to be positioned in the server chassis. In certain embodiments, the left lower rear wall component riser portion 730 includes a left lower riser guide feature 748. In certain embodiments, the left lower riser guide feature 748 is configured to allow a left lower riser to be guided into the server chassis. In certain embodiments, the left lower riser guide feature 748 is configured to allow a left lower riser to be positioned in the server chassis.

In certain embodiments, the rear wall component 700 includes a ground connection portion 750. In certain embodiments, the ground connection portion 750 is configured to physically couple a grounding kit to the server chassis. In certain embodiments, the ground connection portion 750 is configured to physically connect a grounding kit which conforms to a network equipment building system (NEBS) standard to the server chassis.

In certain embodiments, the rear wall component 700 is configured to provide a gripping area 760. In certain embodiments, the gripping area 760 provides the rear wall system with an integrated rear component handle. In certain embodiments, the gripping area defines a recess portion 762 via which fingers of a user may fit between an edge of the rear wall component 420 and a rear wall of the server chassis.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A rear wall component of a rear wall system for an information handling system, comprising:
a center rear wall component portion;
a right rear wall component portion; and,
a left rear wall component portion, the center rear wall component portion, the right rear wall component portion and the left rear wall component portion being constructed from a single piece of material, the center rear wall component portion horizontally extending between the right rear wall component portion and the left rear wall component portion, the right rear wall component portion extending substantially perpendicularly inward from the center rear wall component portion, the left rear wall component portion extending substantially perpendicularly inward from the center rear wall component portion, the right rear wall component portion being configured to mount the rear wall component to a right portion of a rear wall of a server chassis, the left rear wall component portion being configured to mount the rear wall component to a left portion of the rear wall of the server chassis.

2. The rear wall component of claim 1, wherein:
the center rear wall component portion comprises an upper rear wall component riser portion, the upper rear wall component riser portion being configured to physically attach to an upper riser of the information handling system.

3. The rear wall component of claim 1, wherein:
the right rear wall component portion includes a right lower rear wall component riser portion, the right lower rear wall component riser portion being configured to physically attach a lower riser to the information handling system.

4. The rear wall component of claim 3, wherein:
the right lower rear wall component riser portion comprises a right lower riser guide feature, the right lower riser guide feature being configured to allow a lower riser to be guided into the server chassis.

5. The rear wall component of claim 1, wherein:
the left rear wall component portion includes a left lower rear wall component riser portion, the left lower rear wall component riser portion being configured to physically attach a lower riser to the information handling system.

6. The rear wall component of claim 1, further comprising:
a ground connection portion, the ground connection portion being configured to physically couple a grounding kit to the server chassis.

7. A chassis for an information handling system comprising:
a chassis rear wall; and,
a rear wall system, the rear wall system being configured to be mounted to the chassis rear wall, the rear wall system comprising a rear wall component, the rear wall component comprising:
a center rear wall component portion;
a right rear wall component portion; and,
a left rear wall component portion, the center rear wall component portion, the right rear wall component portion and the left rear wall component portion being constructed from a single piece of material, the center rear wall component portion horizontally extending between the right rear wall component portion and the left rear wall component portion, the right rear wall component portion extending substantially perpendicularly inward from the center rear wall component portion, the left rear wall component portion extending substantially perpendicularly inward from the center rear wall component portion, the right rear wall component portion being configured to mount the rear wall component to a right portion of a rear wall of a server chassis, the left rear wall component portion being configured to mount the rear wall component to a left portion of the rear wall of the server chassis.

8. The chassis of claim 7, wherein:
the center rear wall component portion comprises an upper rear wall component riser portion, the upper rear wall component riser portion being configured to physically attach to an upper riser of the information handling system.

9. The chassis of claim 7, wherein:
the right rear wall component portion includes a right lower rear wall component riser portion, the right lower rear wall component riser portion being configured to physically attach a lower riser to the information handling system.

10. The chassis of claim 9, wherein:
the right lower rear wall component riser portion comprises a right lower riser guide feature, the right lower riser guide feature being configured to allow a lower riser to be guided into the server chassis.

11. The chassis of claim 7, wherein:
the left rear wall component portion includes a left lower rear wall component riser portion, the left lower rear wall component riser portion being configured to physically attach a lower riser to the information handling system.

12. The chassis of claim 7, wherein:
the rear wall system further comprises a ground connection portion, the ground connection portion being configured to physically couple a grounding kit to the server chassis.

13. A system comprising:
a processor;
a data bus coupled to the processor; and,
a chassis, the chassis containing the processor and the data bus, the chassis comprising a rear wall system, the rear wall system comprising a rear wall component, the rear wall component comprising:
a center rear wall component portion;
a right rear wall component portion; and,
a left rear wall component portion, the center rear wall component portion, the right rear wall component portion and the left rear wall component portion being constructed from a single piece of material, the center rear wall component portion horizontally extending between the right rear wall component portion and the left rear wall component portion, the right rear wall component portion extending substantially perpendicularly inward from the center rear wall component portion, the left rear wall component portion extending substantially perpendicularly inward from the center rear wall component portion, the right rear wall component portion being configured to mount the rear wall component to a right portion of a rear wall of a server chassis, the left rear wall component portion being configured to mount the rear wall component to a left portion of the rear wall of the server chassis.

14. The system of claim 13, wherein:
the center rear wall component portion comprises an upper rear wall component riser portion, the upper rear wall component riser portion being configured to physically attach to an upper riser of the information handling system.

15. The system of claim 13, wherein:
the right rear wall component portion includes a right lower rear wall component riser portion, the right lower rear wall component riser portion being configured to physically attach a lower riser to the information handling system.

16. The system of claim 15, wherein:
the right lower rear wall component riser portion comprises a right lower riser guide feature, the right lower riser guide feature being configured to allow a lower riser to be guided into the server chassis.

17. The system of claim 13, wherein:
the left rear wall component portion includes a left lower rear wall component riser portion, the left lower rear wall component riser portion being configured to physically attach a lower riser to the information handling system.

18. The system of claim 13, wherein:
the rear wall system further comprises a ground connection portion, the ground connection portion being configured to physically couple a grounding kit to the server chassis.
